(19) United States
(12) Patent Application Publication
(10) Pub. No.: US 2025/0244373 A1
(43) Pub. Date: Jul. 31, 2025

(54) REFERENCE THREE-PHASE VOLTAGE SIGNAL GENERATION DEVICE AND REFERENCE THREE-PHASE VOLTAGE SIGNAL-USING APPARATUS

(71) Applicant: SANSHA ELECTRIC MANUFACTURING CO., LTD., Osaka (JP)

(72) Inventor: Atsushi MAKITANI, Osaka-shi (JP)

(21) Appl. No.: 19/025,289

(22) Filed: Jan. 16, 2025

(30) Foreign Application Priority Data
Jan. 26, 2024 (JP) 2024-010002

(51) Int. Cl. G01R 29/18; H02M 7/5395

(52) U.S. Cl. CPC G01R 29/18; H02M 7/5395

(57) ABSTRACT

A reference three-phase voltage signal generation device includes: an internal three-phase voltage signal generator; a reference three-phase voltage signal generation unit that adds a three-phase voltage manipulated variable to an internal three-phase voltage signal to generate a reference three-phase voltage signal; a first Clarke transformation unit that transforms the reference three-phase voltage signal into a reference two-phase voltage signal; an external voltage signal sensor unit; a second Clarke transformation unit that transforms an external three-phase voltage signal into an external two-phase voltage signal; an error generation unit that generates a two-phase voltage error signal based on the reference two-phase voltage signal and the external two-phase voltage signal; a compensation unit that generates a two-phase voltage manipulated variable based on the two-phase voltage error signal, and an inverse Clarke transformation unit that transforms the two-phase voltage manipulated variable into the three-phase voltage manipulated variable.

### BACKGROUND OF THE INVENTION

This application claims the benefit of foreign priority to Japanese Patent Application No. JP2024-010002, filed Jan. 26, 2024, which is incorporated by reference in its entirety.

### FIELD OF THE INVENTION

The present invention relates to a reference three-phase voltage signal generation device and a reference three-phase voltage signal-using apparatus.

### DESCRIPTION OF RELATED ART

Conventionally, phase locked loop (PLL) circuits have been widely known. JP 63-206164 A (see especially FIG. 1 and the description from line 12 in the upper left column on page 3 to line 3 in the upper right column on page 3) discloses an uninterruptible power source (UPS) in which a PLL circuit is used as a power source synchronous circuit that outputs a synchronous sine wave signal having the same phase as a commercial power source. In the uninterruptible power source, an inverter controlled by pulse width modulation (PWM) according to the synchronous sine wave signal using the PLL circuit outputs an AC voltage synchronized with the voltage of the commercial power source.

### SUMMARY OF THE INVENTION

Uninterruptible power sources are recently required to respond at a high speed to a steep fluctuation of the voltage of a commercial power source. However, the conventional uninterruptible power source uses the zero crossing of the external AC voltage and the internal sine wave for detection of the phase difference in the PLL circuit. In zero-crossing detection, in a case where the external AC voltage has a frequency of, for example, 50 Hz, the control chance (chance of detecting a zero-crossing) occurs 1 time or 2 times in one cycle. Therefore, the conventional uninterruptible power source is restricted by the synchronization processing speed and thus cannot respond at a high speed to the steep fluctuation of the voltage of a commercial power source. Such a response at a high speed to the steep fluctuation of the voltage of a commercial power source may also be required for another power source device interconnected with the commercial power source. Furthermore, a power source device that targets the voltage of a general external three-phase power wiring for synchronization or the like is also preferable to be capable of responding at a high speed to a steep fluctuation of the three-phase voltage of the external three-phase power wiring.

The present invention has been made to solve a problem as described above, and an object of the present invention is to provide a reference three-phase voltage signal generation device and a reference three-phase voltage signal-using apparatus that are capable of responding at a high speed to a steep fluctuation of the three-phase voltage of an external three-phase power wiring targeted for synchronization or the like.

In order to achieve the above object, a reference three-phase voltage signal generation device according to an aspect of the present disclosure comprises: an internal three-phase voltage signal generator that generates an internal three-phase voltage signal; a reference three-phase voltage signal generation unit that adds a three-phase voltage manipulated variable to the internal three-phase voltage signal from the internal three-phase voltage signal generator to obtain a reference three-phase voltage signal, and outputs the reference three-phase voltage signal outside; a first Clarke transformation unit that transforms the reference three-phase voltage signal from the reference three-phase voltage signal generation unit into a reference two-phase voltage signal of an αβ coordinate system by Clarke transformation; an external voltage signal sensor unit that acquires an external three-phase voltage signal from an external three-phase power wiring; a second Clarke transformation unit that applies Clarke transformation to the external three-phase voltage signal from the external voltage signal sensor unit, or applies Clarke transformation to the external three-phase voltage signal and performs multiplication by a matrix for rotation by advance 90° to generate an external two-phase voltage signal of the αβ coordinate system; an error generation unit that generates an error of the reference two-phase voltage signal from the first Clarke transformation unit with respect to the external two-phase voltage signal from the second Clarke transformation unit to generate a two-phase voltage error signal; a compensation unit that applies compensation to the two-phase voltage error signal from the error generation unit to generate a two-phase voltage manipulated variable; and an inverse Clarke transformation unit that transforms the two-phase voltage manipulated variable from the compensation unit into the three-phase voltage manipulated variable of an abc coordinate system by inverse Clarke transformation, and inputs the three-phase voltage manipulated variable to the reference three-phase voltage signal generation unit.

A reference three-phase voltage signal-using apparatus according to another aspect of the present disclosure comprises: the reference three-phase voltage signal generation device; and a three-phase inverter that outputs a three-phase voltage synchronized with a three-phase voltage of the external three-phase power wiring by PWM control according to the reference three-phase voltage signal.

The present disclosure has an effect of providing a reference three-phase voltage signal generation device and a reference three-phase voltage signal-using apparatus that are capable of responding at a high speed to a steep fluctuation of the three-phase voltage of an external three-phase power wiring targeted for synchronization or the like.

### BRIEF DESCRIPTION OF THE DRAWINGS

FIG. 1 is a functional block diagram illustrating an example of a concept of a reference three-phase voltage signal generation device according to First Embodiment of the present disclosure;

FIG. 2 shows a functional block diagram illustrating an example of a configuration of a reference three-phase voltage signal generation device according to Second Embodiment of the present disclosure;

FIG. 3 is a schematic view illustrating a principle model of a generator;

FIG. 4 is a vector diagram of Y connection;

FIG. 5 is an explanatory diagram illustrating a relationship between a generator model and the Euler's formula;

FIG. 6 is a vector diagram expressing the Euler's formula with a vector;

FIG. 7 is a schematic diagram illustrating a rotor vector;

FIG. 8 is a vector diagram illustrating a vector operation for determination of a manipulated variable rotor vector;

FIG. 9 is a diagram illustrating a vector locus of a manipulated variable rotor vector;

FIG. 10 is a waveform diagram illustrating waveforms of signals of units of a reference three-phase voltage signal generation device in a simulation of the reference three-phase voltage signal generation device in a case where an external three-phase voltage signal and an internal three-phase voltage signal are different only in phase;

FIG. 11 is a waveform diagram illustrating waveforms of signals of units of a reference three-phase voltage signal generation device in a simulation of the reference three-phase voltage signal generation device in a case where an external three-phase voltage signal and an internal three-phase voltage signal are different in frequency;

FIG. 12 shows a functional block diagram illustrating an example of a configuration of a reference three-phase voltage signal generation device according to Third Embodiment of the present disclosure;

FIG. 13A is a functional block diagram illustrating an example of a configuration of a reference three-phase voltage signal-using apparatus according to Fourth Embodiment of the present disclosure; and

FIG. 13B is a functional block diagram illustrating an example of a configuration of a reference three-phase voltage signal-using apparatus according to Fifth Embodiment of the present disclosure.

### DETAILED DESCRIPTION OF EMBODIMENTS

A reference three-phase voltage signal generation device according to an aspect of the present disclosure includes: an internal three-phase voltage signal generator that generates an internal three-phase voltage signal; a reference three-phase voltage signal generation unit that adds a three-phase voltage manipulated variable to the internal three-phase voltage signal from the internal three-phase voltage signal generator to obtain a reference three-phase voltage signal, and outputs the reference three-phase voltage signal outside; a first Clarke transformation unit that transforms the reference three-phase voltage signal from the reference three-phase voltage signal generation unit into a reference two-phase voltage signal of an αβ coordinate system by Clarke transformation; an external voltage signal sensor unit that acquires an external three-phase voltage signal from an external three-phase power wiring; a second Clarke transformation unit that applies Clarke transformation to the external three-phase voltage signal from the external voltage signal sensor unit, or applies Clarke transformation to the external three-phase voltage signal and performs multiplication by a matrix for rotation by advance 90° to generate an external two-phase voltage signal of the αβ coordinate system; an error generation unit that generates an error of the reference two-phase voltage signal from the first Clarke transformation unit with respect to the external two-phase voltage signal from the second Clarke transformation unit to generate a two-phase voltage error signal; a compensation unit that applies compensation to the two-phase voltage error signal from the error generation unit to generate a two-phase voltage manipulated variable; and an inverse Clarke transformation unit that transforms the two-phase voltage manipulated variable from the compensation unit into the three-phase voltage manipulated variable of an abc coordinate system by inverse Clarke transformation, and inputs the three-phase voltage manipulated variable to the reference three-phase voltage signal generation unit.

Here, the “internal three-phase voltage signal” includes a “sine wave internal three-phase voltage signal”, which is an effective component, and a “cosine wave internal three-phase voltage signal”, which is an ineffective component. The “external three-phase voltage signal” includes only a “sine wave external three-phase voltage signal”, which is an effective component. The “two-phase voltage signal” includes a “sine wave two-phase voltage signal”, which is an effective component, and a “cosine wave reference two-phase voltage signal”, which is an ineffective component. The “two-phase voltage error signal” includes a “sine wave two-phase voltage error signal”, which is an effective component, and a “cosine wave two-phase voltage error signal”, which is an ineffective component. The “two-phase voltage manipulated variable” includes a “sine wave two-phase voltage manipulated variable”, which is an effective component, and a “cosine wave two-phase voltage manipulated variable”, which is an ineffective component. The “three-phase voltage manipulated variable” includes a “sine wave three-phase voltage manipulated variable”, which is an effective component, and a “cosine wave three-phase voltage manipulated variable”, which is an ineffective component. These definitions are reasonable since the cosine wave internal three-phase voltage signal has a phase advanced by only 90° (π/2 [rad]) with respect to that of the sine wave internal three-phase voltage signal.

According to this configuration, first, the three-phase voltage manipulated variable is added to the internal three-phase voltage signal from the internal three-phase voltage signal generator, and the reference three-phase voltage signal obtained by the addition is output to the outside. Next, the reference three-phase voltage signal from the reference three-phase voltage signal generation unit is transformed into the reference two-phase voltage signal of the ap coordinate system by Clarke transformation. The external three-phase voltage signal from the external voltage signal sensor unit is subjected to Clarke transformation or Clarke transformation and multiplication by the matrix for rotation, and thus transformed into the external two-phase voltage signal of the αβ coordinate system. The αβ coordinate system is an orthogonal coordinate system, and therefore the reference two-phase voltage signal and the external two-phase voltage signal specify a reference rotor vector and an external rotor vector, respectively. The reference rotor vector and the external rotor vector rotate at angular velocities corresponding to the frequencies of the reference three-phase voltage signal and the external three-phase voltage signal before Clarke transformation, respectively.

Next, the error of the reference two-phase voltage signal with respect to the external two-phase voltage signal is generated to generate the two-phase voltage error signal, and compensation is applied to the two-phase voltage error signal to generate the two-phase voltage manipulated variable. This processing corresponds to processing in which a reference rotor vector is subtracted from an external rotor vector by a vector operation to obtain a manipulated variable rotor vector.

Next, the two-phase voltage manipulated variable is transformed into the three-phase voltage manipulated variable of the abc coordinate system by inverse Clarke transformation, and the three-phase voltage manipulated variable is added to the internal three-phase voltage signal. This processing corresponds to processing of adding the manipulated variable rotor vector to the reference rotor vector on the time axis.

The above closed-loop feedback control makes the reference rotor vector match the external rotor vector or have a leading phase difference of 90° with respect to the external rotor vector to generate the reference three-phase voltage signal that is synchronized with the external three-phase voltage signal or has a phase difference corresponding to the ineffective component.

The speed of the above reference three-phase voltage signal generation processing is determined by the speed of sampling the external three-phase voltage signal. This sampling can be performed, for example, at 6 kHz, and in a case where the external three-phase voltage signal has a frequency of 50 Hz, the control chance (chance of acquiring the external three-phase voltage signal) occurs 120 times in one cycle of the external three-phase voltage signal. Meanwhile, in zero-crossing detection, in a case where the external three-phase voltage has a frequency of 50 Hz, the control chance (chance of detecting a zero-crossing) occurs 1 time or 2 times in one cycle of the external three-phase voltage signal. Therefore, in the above configuration, the speed of the reference three-phase voltage signal generation processing (synchronization or processing of advancing a phase by 90°) is remarkably faster than the processing speed in the conventional zero-crossing detection, and as a result, an apparatus using the reference three-phase voltage signal can respond at a high speed to a steep fluctuation of the voltage of an external three-phase power targeted for synchronization or the like.

The reference three-phase voltage signal generation device may be such that the internal three-phase voltage signal includes an internal U-phase voltage signal, an internal V-phase voltage signal, and an internal W-phase voltage signal that are an internal a voltage signal, an internal b voltage signal, and an internal c voltage signal in the abc coordinate system, respectively, the external three-phase voltage signal includes an external U-phase voltage signal, an external V-phase voltage signal, and an external W-phase voltage signal that are an external a voltage signal, an external b voltage signal, and an external c voltage signal in the abc c oordinate system, respectively, the reference three-phase voltage signal generation unit adds an a voltage manipulated variable, a b voltage manipulated variable, and a c voltage manipulated variable of the three-phase voltage manipulated variable to the internal a voltage signal, the internal b voltage signal, and the internal c voltage signal of the internal three-phase voltage signal from the internal three-phase voltage signal generator, respectively, to obtain the reference three-phase voltage signal including a reference U-phase voltage signal as a reference a voltage signal, a reference V-phase voltage signal as a reference b voltage signal, and a reference W-phase voltage signal as a reference c voltage signal, and outputs the reference three-phase voltage signal outside, the first Clarke transformation unit transforms the reference three-phase voltage signal including the reference a voltage signal, the reference b voltage signal, and the reference c voltage signal from the reference three-phase voltage signal generation unit into the reference two-phase voltage signal including a reference α voltage signal and a reference β voltage signal of the αβ coordinate system by Clarke transformation, the second Clarke transformation unit applies Clarke transformation to the external three-phase voltage signal including the external a voltage signal, the external b voltage signal, and the external c voltage signal from the external voltage signal sensor unit, or applies Clarke transformation to the external three-phase voltage signal and performs multiplication by a matrix for rotation by advance 90° to generate the external two-phase voltage signal including an external α voltage signal and an external β voltage signal of the αβ coordinate system, the error generation unit generates the two-phase voltage error signal including an α voltage error signal and a β voltage error signal that are an error of the reference α voltage signal and an error of the reference β voltage signal of the reference two-phase voltage signal from the first Clarke transformation unit with respect to the external α voltage signal and the external β voltage signal of the external two-phase voltage signal from the second Clarke transformation unit, respectively, the compensation unit applies compensation to each of the α voltage error signal and the β voltage error signal of the two-phase voltage error signal from the error generation unit to generate the two-phase voltage manipulated variable including an α voltage manipulated variable and a β voltage manipulated variable, and the inverse Clarke transformation unit transforms the two-phase voltage manipulated variable including the α voltage manipulated variable and the β voltage manipulated variable from the compensation unit into the three-phase voltage manipulated variable including the a voltage manipulated variable, the b voltage manipulated variable, and the c voltage manipulated variable of the abc coordinate system by inverse Clarke transformation, and inputs the three-phase voltage manipulated variable to the reference three-phase voltage signal generation unit.

Here, the “reference a voltage signal”, the “reference b voltage signal”, and the “reference c voltage signal” include a “sine wave reference a voltage signal” and a “cosine wave reference a voltage signal”, a “sine wave reference b voltage signal” and a “cosine wave reference b voltage signal”, and a “sine wave reference c voltage signal” and a “cosine wave reference c voltage signal”, respectively. The “external a voltage signal”, the “external b voltage signal”, and the “external c voltage signal” include a “sine wave external a voltage signal” and a “cosine wave external a voltage signal”, a “sine wave external b voltage signal” and a “cosine wave external b voltage signal”, and a “sine wave external c voltage signal” and a “cosine wave external c voltage signal”, respectively.

The “reference α voltage signal” and the “reference β voltage signal” include a “sine wave reference α voltage signal” and a “cosine wave reference α voltage signal”, and a “sine wave reference β voltage signal” and a “cosine wave reference β voltage signal”, respectively. The “external α voltage signal” and the “external β voltage signal” include a “sine wave external α voltage signal” and a “cosine wave external α voltage signal”, and a “sine wave external β voltage signal” and a “cosine wave external β voltage signal”, respectively.

The “α voltage error signal” and the “β voltage error signal” include a “sine wave α voltage error signal” and a “cosine wave α voltage error signal”, and a “sine wave β voltage error signal” and a “cosine wave β voltage error signal”, respectively.

The “α voltage manipulated variable” and the “β voltage manipulated variable” include a “sine wave α voltage manipulated variable” and a “cosine wave α voltage manipulated variable”, and a “sine wave β voltage manipulated variable” and a “cosine wave β voltage manipulated variable”, respectively.

According to this configuration, a reference three-phase voltage generation device can be suitably constructed.

The reference three-phase voltage signal generation device may be such that the reference three-phase voltage signal generation unit adds a sine wave three-phase voltage manipulated variable to the internal three-phase voltage signal from the internal three-phase voltage signal generator to obtain a sine wave reference three-phase voltage signal, and outputs the sine wave reference three-phase voltage signal outside, the first Clarke transformation unit transforms the sine wave reference three-phase voltage signal from the reference three-phase voltage signal generation unit into a sine wave reference two-phase voltage signal of the αβ coordinate system by Clarke transformation, the second Clarke transformation unit applies Clarke transformation to the external three-phase voltage signal from the external voltage signal sensor unit to generate a sine wave external two-phase voltage signal of the αβ coordinate system, the error generation unit generates a sine wave two-phase voltage error signal as an error of the sine wave reference two-phase voltage signal from the first Clarke transformation unit with respect to the sine wave external two-phase voltage signal from the second Clarke transformation unit, the compensation unit applies compensation to the sine wave two-phase voltage error signal from the error generation unit to generate a sine wave two-phase voltage manipulated variable, and the inverse Clarke transformation unit transforms the sine wave two-phase voltage manipulated variable from the compensation unit into the sine wave three-phase voltage manipulated variable of the abc coordinate system by inverse Clarke transformation, and inputs the sine wave three-phase voltage manipulated variable to the reference three-phase voltage signal generation unit.

According to this configuration, the external three-phase voltage signal is a sine wave external three-phase voltage signal as an effective component. The second Clarke transformation unit applies Clarke transformation to the sine wave external three-phase voltage signal to generate the sine wave external two-phase voltage signal of the αβ coordinate system. The error generation unit generates the sine wave two-phase voltage error signal based on the sine wave external two-phase voltage signal. The compensation unit generates the sine wave two-phase voltage manipulated variable based on the sine wave two-phase voltage error signal. The inverse Clarke transformation unit transforms the sine wave two-phase voltage manipulated variable into the sine wave three-phase voltage manipulated variable by inverse Clarke transformation. The reference three-phase voltage signal generation unit adds the sine wave three-phase voltage manipulated variable to the internal three-phase voltage signal from the internal three-phase voltage signal generator, and outputs the sine wave reference three-phase voltage signal obtained by the addition to the outside. The above closed-loop feedback control synchronizes the sine wave reference three-phase voltage signal with the external three-phase voltage signal. As a result, the reference three-phase voltage signal generation device can be provided that outputs a sine wave reference three-phase voltage signal synchronized with a three-phase voltage of the effective component of an external three-phase power.

The reference three-phase voltage signal generation device may be such that the reference three-phase voltage signal generation unit adds a cosine wave three-phase voltage manipulated variable to the internal three-phase voltage signal from the internal three-phase voltage signal generator to obtain a cosine wave reference three-phase voltage signal, and outputs the cosine wave reference three-phase voltage signal outside, the first Clarke transformation unit transforms the cosine wave reference three-phase voltage signal from the reference three-phase voltage signal generation unit into a cosine wave reference two-phase voltage signal of the αβ coordinate system by Clarke transformation, the second Clarke transformation unit includes a Clarke transformation unit and a rotation matrix multiplication unit, the Clarke transformation unit applies Clarke transformation to the external three-phase voltage signal from the external voltage signal sensor unit to generate a sine wave external two-phase voltage signal of the αβ coordinate system, the rotation matrix multiplication unit multiplies the sine wave external two-phase voltage signal by a matrix for rotation by advance 90° to generate a cosine wave external two-phase voltage signal, the error generation unit generates a cosine wave two-phase voltage error signal as an error of the cosine wave reference two-phase voltage signal from the first Clarke transformation unit with respect to the cosine wave external two-phase voltage signal from the rotation matrix multiplication unit of the second Clarke transformation unit, the compensation unit applies compensation to the cosine wave two-phase voltage error signal from the error generation unit to generate a cosine wave two-phase voltage manipulated variable, and the inverse Clarke transformation unit transforms the cosine wave two-phase voltage manipulated variable from the compensation unit into the cosine wave three-phase voltage manipulated variable of the abc coordinate system by inverse Clarke transformation, and inputs the cosine wave three-phase voltage manipulated variable to the reference three-phase voltage signal generation unit.

According to this configuration, fundamentally, the internal three-phase voltage signal has a phase changed for synchronization by feedback control, and therefore the initial phase is not particularly limited. The external three-phase voltage signal is a sine wave external three-phase voltage signal as an effective component. The second Clarke transformation unit applies Clarke transformation to the sine wave external three-phase voltage signal to generate the sine wave external two-phase voltage signal of the αβ coordinate system, and multiplies the sine wave external two-phase voltage signal by the matrix for rotation by advance 90° to generate the cosine wave external two-phase voltage signal. The error generation unit generates the cosine wave two-phase voltage error signal based on the cosine wave external two-phase voltage signal. The compensation unit generates the cosine wave two-phase voltage manipulated variable based on the cosine wave two-phase voltage error signal. The inverse Clarke transformation unit transforms the cosine wave two-phase voltage manipulated variable into the cosine wave three-phase voltage manipulated variable by inverse Clarke transformation. The reference three-phase voltage signal generation unit adds the cosine wave three-phase voltage manipulated variable to the internal three-phase voltage signal from the internal three-phase voltage signal generator, and outputs the cosine wave reference three-phase voltage signal obtained by the addition to the outside. The above closed-loop feedback control makes the cosine wave reference three-phase voltage have a phase corresponding to a cosine wave with respect to an external three-phase power voltage having a sine wave. As a result, the reference three-phase voltage signal generation device can be provided that outputs a cosine wave reference three-phase voltage signal corresponding to a three-phase voltage signal of the ineffective component of an external three-phase power.

The compensation unit may perform proportional-integral (PI) compensation on the two-phase voltage error signal. According to this configuration, compensation can be suitably applied to the two-phase voltage error signal.

A reference three-phase voltage signal-using apparatus according to another aspect of the present disclosure includes: any reference three-phase voltage signal generation device described above; and a three-phase inverter that outputs a three-phase voltage synchronized with a three-phase voltage of the external three-phase power wiring by PWM control according to the reference three-phase voltage signal.

According to this configuration, the reference three-phase voltage signal-using apparatus can be provided that is capable of responding at a high speed to a steep fluctuation of the three-phase voltage of an external three-phase power wiring targeted for synchronization or the like.

The reference three-phase voltage signal-using apparatus may be such that the reference three-phase voltage signal generation device outputs the reference three-phase voltage signal from the reference three-phase voltage signal generation unit, the reference three-phase voltage signal is synchronized with a three-phase voltage of a power supply system as the external three-phase power wiring, and the three-phase inverter outputs a three-phase voltage synchronized with the three-phase voltage of the power supply system by PWM control according to the reference three-phase voltage signal.

According to this configuration, an interconnection power source can be provided that is capable of responding at a high speed to a steep fluctuation of the three-phase voltage of a power supply system targeted for synchronization or the like.

Hereinafter, specific embodiments of the present disclosure will be described with reference to the drawings. In the following description, the same or corresponding elements are denoted by the same reference signs throughout all the drawings, and redundant description of the elements will be omitted. The drawings described below are for describing the present disclosure, and therefore in the drawings, an element unrelated to the present disclosure may be omitted, a dimension may be inaccurate for exaggeration or the like, simplification may be performed, the forms of elements corresponding to each other may be inconsistent in a plurality of drawings, or a waveform in a waveform diagram may be inaccurate. The present disclosure is not limited to the following embodiments.

### First Embodiment

### [Configuration]

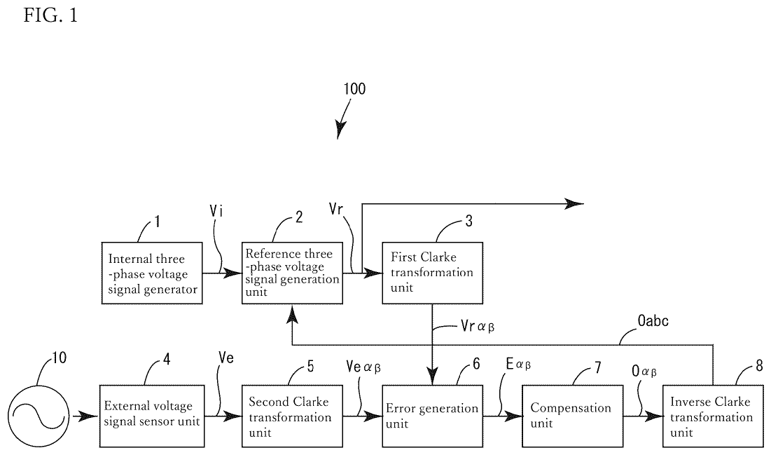

FIG. 1 is a functional block diagram illustrating an example of a concept of a reference three-phase voltage signal generation device 100 according to First Embodiment of the present disclosure.

Referring to FIG. 1, the reference three-phase voltage signal generation device 100 of First Embodiment includes an internal three-phase voltage signal generator 1, a reference three-phase voltage signal generation unit 2, a first Clarke transformation unit 3, an external voltage signal sensor unit 4, a second Clarke transformation unit 5, an error generation unit 6, a compensation unit 7, and an inverse Clarke transformation unit 8.

The internal three-phase voltage signal generator 1 generates an internal three-phase voltage signal Vi. The reference three-phase voltage signal generation unit 2 adds a three-phase voltage manipulated variable Oabc to the internal three-phase voltage signal Vi from the internal three-phase voltage signal generator 1, and outputs a reference three-phase voltage signal Vr obtained by the addition to the outside. The first Clarke transformation unit 3 transforms the reference three-phase voltage signal Vr from the reference three-phase voltage signal generation unit 2 into a reference two-phase voltage signal Vrαβ of an αβ coordinate system by Clarke transformation.

Meanwhile, the external voltage signal sensor unit 4 acquires an external three-phase voltage signal Ve from an external three-phase power wiring 10. The second Clarke transformation unit 5 applies Clarke transformation to the external three-phase voltage signal Ve from the external voltage signal sensor unit 4, or applies Clarke transformation to the external three-phase voltage signal Ve and performs multiplication by a matrix for rotation by advance 90° to generate an external two-phase voltage signal Veαβ of the αβ coordinate system.

The error generation unit 6 generates an error of the reference two-phase voltage signal Vrαβ from the first Clarke transformation unit 3 with respect to the external two-phase voltage signal Veαβ from the second Clarke transformation unit 5 to generate a two-phase voltage error signal Eαβ. The compensation unit 7 applies compensation to the two-phase voltage error signal Eαβ from the error generation unit 6 to generate a two-phase voltage manipulated variable Oαβ. The inverse Clarke transformation unit 8 transforms the two-phase voltage manipulated variable Oαβ from the compensation unit 7 into the three-phase voltage manipulated variable Oabc of an abc coordinate system by inverse Clarke transformation, and inputs the three-phase voltage manipulated variable Oabc to the reference three-phase voltage signal generation unit 2.

### [Operation]

In the reference three-phase voltage signal generation device 100, first, the three-phase voltage manipulated variable Oabc is added to the internal three-phase voltage signal Vi from the internal three-phase voltage signal generator 1, and the reference three-phase voltage signal Vr obtained by the addition is output to the outside. Next, the reference three-phase voltage signal Vr from the reference three-phase voltage signal generation unit 2 is transformed into the reference two-phase voltage signal Vrαβ of the αβ coordinate system by Clarke transformation. The external three-phase voltage signal Ve from the external voltage signal sensor unit 4 is subjected to Clarke transformation or Clarke transformation and multiplication by the matrix for rotation by advance 90°, and thus transformed into the external two-phase voltage signal Veαβ of the αβ coordinate system. The αβ coordinate system is an orthogonal coordinate system, and therefore the reference two-phase voltage signal Vrαβ and the external two-phase voltage signal Veαβ specify a reference rotor vector and an external rotor vector, respectively. The reference rotor vector and the external rotor vector rotate at an angular velocity corresponding to the frequency of the reference three-phase voltage signal Vr and an angular velocity corresponding to the frequency of the external three-phase voltage signal Ve before Clarke transformation, respectively.

Next, the error of the reference two-phase voltage signal Vrαβ with respect to the external two-phase voltage signal Veαβ is generated to generate the two-phase voltage error signal Eαβ, and compensation is applied to the two-phase voltage error signal Eαβ to generate the two-phase voltage manipulated variable Oαβ. This processing corresponds to processing in which a reference rotor vector is subtracted from an external rotor vector by a vector operation to obtain a manipulated variable rotor vector.

Next, the two-phase voltage manipulated variable Oαβ is transformed into the three-phase voltage manipulated variable Oabc of the abc coordinate system by inverse Clarke transformation, and the three-phase voltage manipulated variable Oabc is added to the internal three-phase voltage signal Vi. This processing corresponds to processing of adding the manipulated variable rotor vector to the reference rotor vector on the time axis.

The above closed-loop feedback control makes the reference rotor vector match the external rotor vector or have a leading phase difference of 90° with respect to the external rotor vector to generate the reference three-phase voltage signal Vr that is synchronized with the external three-phase voltage signal Ve or has a phase difference corresponding to the ineffective component. The reference rotor vector, the external rotor vector, and the manipulated variable rotor vector will be described in detail in Second Embodiment.

The speed of the above reference three-phase voltage signal generation processing is determined by the frequency of sampling the external three-phase voltage signal Ve. This sampling can be performed, for example, at a frequency of 6 kHz, and in a case where the external three-phase voltage signal Ve has a frequency of 50 Hz, the control chance (chance of acquiring the external three-phase voltage signal) occurs 120 times in one cycle. Meanwhile, in zero-crossing detection, in a case where the external three-phase voltage signal Ve has a frequency of 50 Hz, the control chance (chance of detecting a zero-crossing) occurs 1 time or 2 times in one cycle. Therefore, in the reference three-phase voltage signal generation device 100, the speed of the reference three-phase voltage signal generation processing (synchronization or processing of advancing a phase by 90°) is remarkably faster than the processing speed in the conventional zero-crossing detection, and as a result, an apparatus using the reference three-phase voltage signal Vr can respond at a high speed to a steep fluctuation of the voltage of the external three-phase power wiring 10.

The reference three-phase voltage signal generation device 100 according to First Embodiment has Second Embodiment in which the second Clarke transformation unit 5 only applies Clarke transformation to the external three-phase voltage signal Ve to generate a sine wave reference three-phase voltage signal, and Third Embodiment in which the second Clarke transformation unit 5 applies Clarke transformation to the external three-phase voltage signal Ve and performs multiplication by a matrix for rotation by advance 90° to generate a cosine wave reference three-phase voltage signal.

A detailed configuration of First Embodiment will be described by Second Embodiment and Third Embodiment described below.

### Second Embodiment

A reference three-phase voltage signal generation device 100A according to Second Embodiment is the reference three-phase voltage signal generation device 100 of First Embodiment in which the second Clarke transformation unit 5 only applies Clarke transformation to the external three-phase voltage signal Ve. Therefore, the reference three-phase voltage signal generation device 100A generates a sine wave reference three-phase voltage signal Vrs.

### [Configuration]

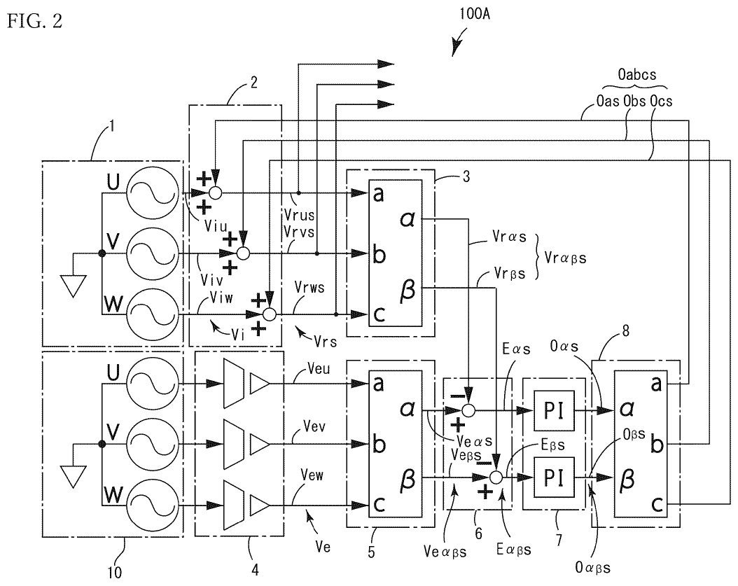

FIG. 2 shows a functional block diagram illustrating an example of a configuration of the reference three-phase voltage signal generation device 100A according to Second Embodiment of the present disclosure. Hereinafter, the configuration of the reference three-phase voltage signal generation device 100A will be described in detail with reference to FIG. 2.

### <Internal Three-Phase Voltage Signal Generator 1>

An internal three-phase voltage signal generator 1 generates an internal three-phase voltage signal Vi including an internal U-phase voltage signal Viu, an internal V-phase voltage signal Viv, and an internal W-phase voltage signal Viw. The internal U-phase voltage signal Viu, the internal V-phase voltage signal Viv, and the internal W-phase voltage signal Viw are an internal a voltage signal, an internal b voltage signal, and an internal c voltage signal in the abc coordinate system, respectively.

The internal three-phase voltage signal generator 1 is not particularly limited as long as it can generate a sine wave signal. Examples of the internal three-phase voltage signal generator 1 include a capacitor-resistor (CR) oscillator circuit, a Hartley oscillator circuit, and a Colpitts oscillator circuit.

### <Reference Three-Phase Voltage Signal Generation Unit 2>

A reference three-phase voltage signal generation unit 2 adds a sine wave a voltage manipulated variable Oas, a sine wave b voltage manipulated variable Obs, and a sine wave c voltage manipulated variable Ocs of a sine wave three-phase voltage manipulated variable to the internal a voltage signal, the internal b voltage signal, and the internal c voltage signal of the internal three-phase voltage signal Vi from the internal three-phase voltage signal generator 1, respectively, to obtain a sine wave reference three-phase voltage signal Vrs including a sine wave reference U-phase voltage signal Vrus as a sine wave reference a voltage signal, a sine wave reference V-phase voltage signal Vrvs as a sine wave reference b voltage signal, and a sine wave reference W-phase voltage signal Vrws as a sine wave reference c voltage signal, and outputs the sine wave reference three-phase voltage signal Vrs to the outside.

The reference three-phase voltage signal generation unit 2 is not particularly limited as long as it can add a signal. The reference three-phase voltage signal generation unit 2 includes, for example, three adders for a U phase, a V phase, and a W phase. These adders may be constituted by either an electronic circuit or software.

### <First Clarke Transformation Unit 3>

A first Clarke transformation unit 3 transforms the sine wave reference three-phase voltage signal Vrs including the sine wave reference a voltage signal (sine wave reference U-phase voltage signal Vrus), the sine wave reference b voltage signal (sine wave reference V-phase voltage signal Vrvs), and the sine wave reference c voltage signal (sine wave reference W-phase voltage signal Vrws) from the reference three-phase voltage signal generation unit 2 into a sine wave reference two-phase voltage signal Vrαβs including a sine wave reference α voltage signal Vrαs and a sine wave reference β voltage signal Vrβs of the αβ coordinate system by Clarke transformation.

The first Clarke transformation unit 3 is not particularly limited as long as it can perform Clarke transformation. For example, the first Clarke transformation unit 3 is constituted by software.

### <External Voltage Signal Sensor Unit 4>

An external voltage signal sensor unit 4 acquires an external three-phase voltage signal Ve including an external U-phase voltage signal Veu, an external V-phase voltage signal Vev, and an external W-phase voltage signal Vew from an external three-phase power wiring 10. The external U-phase voltage signal Veu, the external V-phase voltage signal Vev, and the external W-phase voltage signal Vew are an external a voltage signal, an external b voltage signal, and an external c voltage signal in the abc coordinate system, respectively.

The external voltage signal sensor unit 4 includes an external U-phase voltage signal sensor, an external V-phase voltage signal sensor, and an external W-phase voltage signal sensor. The external voltage signal sensor unit 4 is not particularly limited as long as it can acquire the external three-phase voltage signal Ve. Examples of the voltage sensor include a voltmeter and a hall element.

### <Second Clarke Transformation Unit 5>

A second Clarke transformation unit 5 transforms the external three-phase voltage signal Ve including the external a voltage signal (external U-phase voltage signal Veu), the external b voltage signal (external V-phase voltage signal Vev), and the external c voltage signal (external W-phase voltage signal Vew) from the external voltage signal sensor unit 4 into a sine wave external two-phase voltage signal Veαβs including a sine wave external α voltage signal Veαs and a sine wave external β voltage signal Veβs of the αβ coordinate system by Clarke transformation.

The second Clarke transformation unit 5 is not particularly limited as long as it can perform Clarke transformation. For example, the second Clarke transformation unit 5 is constituted by software.

### <Error Generation Unit 6>

An error generation unit 6 generates a sine wave two-phase voltage error signal Eαβs including a sine wave α voltage error signal Eαs and a sine wave β voltage error signal Eβs, which are errors of the sine wave reference α voltage signal Vrαs and the sine wave reference β voltage signal Vrβs of the sine wave reference two-phase voltage signal Vrαβs from the first Clarke transformation unit 3 with respect to the sine wave external α voltage signal Veαs and the sine wave external β voltage signal Veβs of the sine wave external two-phase voltage signal Veαβs from the second Clarke transformation unit 5, respectively.

The error generation unit 6 includes, for example, two subtractors for generation of the sine wave α voltage error signal Eαs and generation of the sine wave β voltage error signal Eβs. The subtractor for generation of the sine wave α voltage error signal Eαs subtracts the sine wave reference α voltage signal Vrαs from the sine wave external α voltage signal Veαs. The subtractor for generation of the sine wave β voltage error signal Eβs subtracts the sine wave reference β voltage signal Vrβs from the sine wave external β voltage signal Veβs. These subtractors may be constituted by either an electronic circuit or software.

The error generation unit 6 may include a phase inversion unit that inverts each of the phase of the sine wave reference α voltage signal Vrαs and the phase of the sine wave reference β voltage signal Vrβs of the sine wave reference two-phase voltage signal Vrαβs, and an addition unit that adds the sine wave reference α voltage signal Vrαs and the sine wave reference β voltage signal Vrβs of the sine wave reference two-phase voltage signal Vrαβs after the phase inversion to the sine wave external α voltage signal Veαs and the sine wave external β voltage signal Veβs of the sine wave external two-phase voltage signal Veαβs, respectively. The phase inversion unit and the addition unit may be constituted by either an electronic circuit or software.

### <Compensation Unit 7>

A compensation unit 7 applies compensation to each of the sine wave α voltage error signal Eαs and the sine wave β voltage error signal Eβs of the sine wave two-phase voltage error signal Eαβs from the error generation unit 6 to generate a sine wave two-phase voltage manipulated variable Oαβs including a sine wave α voltage manipulated variable Oαs and a sine wave β voltage manipulated variable Oβs. For example, proportional (P) compensation, PI compensation, proportional-integral-derivative (PID) compensation, or the like is used as the compensation. Here, for example, PI compensation is used. The compensation unit 7 may be constituted by either an electronic circuit or software.

### <Inverse Clarke Transformation Unit 8>

An inverse Clarke transformation unit 8 transforms the sine wave two-phase voltage manipulated variable Oαβs including the sine wave α voltage manipulated variable Oαs and the sine wave 3 voltage manipulated variable Oβs from the compensation unit 7 into a sine wave three-phase voltage manipulated variable Oabcs including the sine wave a voltage manipulated variable Oas, the sine wave b voltage manipulated variable Obs, and the sine wave c voltage manipulated variable Ocs of the abc coordinate system by inverse Clarke transformation, and inputs the sine wave three-phase voltage manipulated variable Oabcs to the reference three-phase voltage signal generation unit 2. The inverse Clarke transformation unit 8 is not particularly limited as long as it can perform inverse Clarke transformation. For example, the inverse Clarke transformation unit 8 may be constituted by software.

### <Configuration by Software>

As described above, the reference three-phase voltage signal generation unit 2, the first Clarke transformation unit 3, the second Clarke transformation unit 5, the error generation unit 6, the compensation unit 7, and the inverse Clarke transformation unit 8 can be configured by software. In this case, for example, an arithmetic unit including a processor and a memory is used, the memory of the arithmetic unit stores a predetermined program for execution of the functions of the reference three-phase voltage signal generation unit 2, the first Clarke transformation unit 3, the second Clarke transformation unit 5, the error generation unit 6, the compensation unit 7, and the inverse Clarke transformation unit 8, and the processor reads and executes the predetermined program to realize each of the reference three-phase voltage signal generation unit 2, the first Clarke transformation unit 3, the second Clarke transformation unit 5, the error generation unit 6, the compensation unit 7, and the inverse Clarke transformation unit 8 as a functional block. In this case, the arithmetic unit operates as the reference three-phase voltage signal generation unit 2, the first Clarke transformation unit 3, the second Clarke transformation unit 5, the error generation unit 6, the compensation unit 7, and the inverse Clarke transformation unit 8. The arithmetic unit can include, for example, a computer, a personal computer, a microcontroller, a micro processing unit (MPU), a field programmable gate array (FPGA), or a programmable logic controller (PLC).

Here, the functions of the elements disclosed herein can be executed using circuitry or processing circuitry including a generic processor, a special purpose processor, an integrated circuit, an application specific integrated circuit (ASIC), a conventional circuit, and/or a combination thereof configured or programmed to execute the disclosed functions. A processor includes a transistor and another circuit, and therefore is considered to be a processing circuitry or circuitry. In the present disclosure, the term “circuit” or “unit” refers to hardware that executes recited functions or hardware programmed to execute recited functions. The hardware may be the hardware disclosed herein, or may be any other known hardware that is programmed or configured to execute the recited functions. In a case where the hardware is a processor considered to be a circuitry, the term “circuit” or “unit” refers to a combination of hardware and software, and the software is used for configuration of the hardware and/or the processor.

### <External Three-Phase Power Wiring 10>

The external three-phase power wiring 10 is not particularly limited as long as it is an external three-phase power source targeted by the reference three-phase voltage signal generation device 100A for synchronization or the like. Examples of the external three-phase power source include commercial power sources (power supply systems) and general three-phase power sources other than the commercial power sources.

### [Principle]

Since the present disclosure is original (creative), its principle will be sequentially described.

### <Clarke Transformation and Inverse Clarke Transformation>

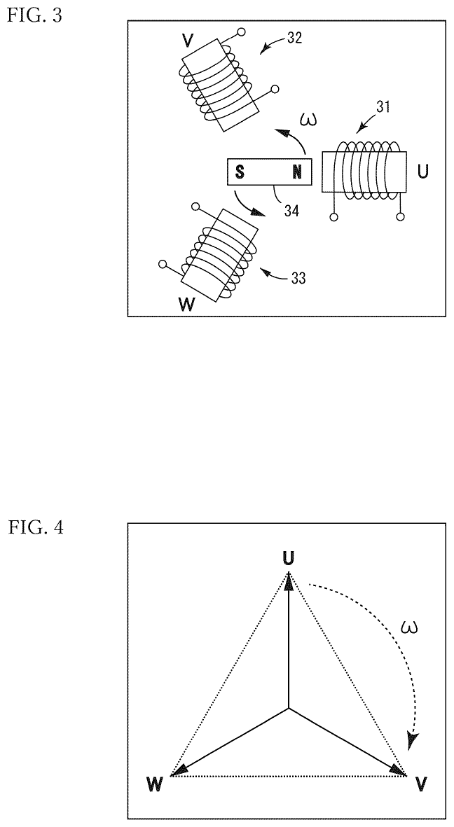

Clarke transformation is also called three-phase two-phase transformation or abc-αβ transformation. Understanding this needs understanding the principle of a generator. FIG. 3 is a schematic view illustrating a principle model of a generator. FIG. 4 is a vector diagram of Y connection.

Referring to FIG. 3, three coils 31 to 33 of a U-phase coil 31, a V-phase coil 32, and a W-phase coil 33 are arranged at a bank angle of 120°, and a magnet 34 is arranged at the center thereof. The magnet 34 is referred to as a rotor. The rotor rotates counterclockwise at an angular velocity ω. When the rotor approaches the coils 31 to 33, a voltage is induced in the coils 31 to 33. This phenomenon is called electromagnetic induction. The arrangement of the coils 31 to 33 is three-phase Y connection. However, the order of the phases seems to be inverse. This is because FIG. 3 is a “view in which the coils are stationary and the rotor is rotating”. When viewed from the rotating rotor, the coils 31 to 33 seems to rotate clockwise. The order of passing the rotor is to be U phase→V phase→W phase. Then, a familiar vector diagram of Y connection is obtained as illustrated in FIG. 4.

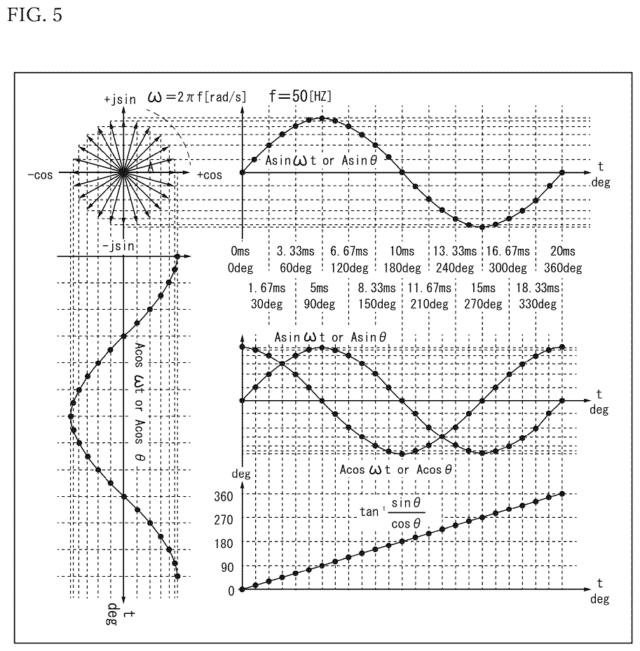

FIG. 5 is an explanatory diagram illustrating a relationship between a generator model and the Euler's formula. In FIG. 5, the angular velocity ω=2πf [rad/s], and the frequency f=50 [Hz]. It is assumed that the angular velocity ω and the time t are synchronized.

Returning to the above, focusing on the U-phase coil 31 of the generator model clarifies the relationship in FIG. 5. A sine wave and a cosine wave are visualized by regarding the upper left vectors in FIG. 5 as the rotor and plotting the vertexes. When the rotor is horizontal, the rotor comes closest to the coil 31, and the largest voltage is induced. Therefore, the cosine wave in FIG. 5 is a waveform generally called a sine wave, and indicates an effective component. Meanwhile, the sine wave indicates an ineffective component.

Thus, the upper left vectors in FIG. 5 are expressed by the following two formulas. The following two formulas are the “Euler's formula”.

$${Ae}^{j ω t} = A ( cos ω t + j sin ω t )$$

$${Ae}^{j θ} = A ( cos θ + j sin θ )$$

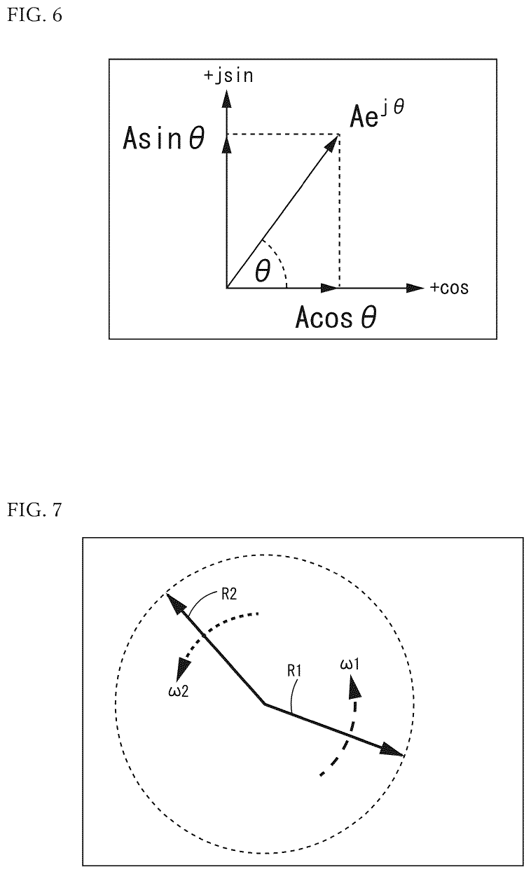

FIG. 6 is a vector diagram expressing the “Euler's formula” with a vector. The “Euler's formula” is expressed with a vector as in FIG. 6. In other words, the rotor can be expressed by combining the cosine wave component and the sine wave component. Although the U-phase coil 31 is focused here, the same applies to the V-phase coil 32 and the W-phase coil 33. Thus, the three phases can be collectively expressed.

That is, the “three waveforms of three phases” can be expressed by “two waveforms (cosine wave/sine wave) obtained by decomposing the rotor vector”. This is why the transformation is called “three-phase two-phase transformation”. Alternatively, the “three waveforms of three phases” is denoted by [a b c], and the cosine wave and the sine wave of the “two waveforms (cosine wave/sine wave) obtained by decomposing the rotor vector” are denoted by a and 3, respectively, and thus the transformation is also called “abc-αβ transformation”.

As in the case of a general vector, the scalar quantity and the angle can be determined with the following two formulas.

$$\vert {Ae}^{j θ} \vert = \sqrt{{( A sin θ )}^{2} + {( A cos θ )}^{2}} \qquad [ Mathematical Formula 1 ]$$

$$θ = {tan}^{- 1} \frac{A sin θ}{A cos θ}$$

The Clarke transformation is expressed by the following determinants.

$$[ \begin{matrix}{v}_{α} \\ {v}_{β}\end{matrix} ] = \frac{2}{3} [ \begin{matrix}1 & - \frac{1}{2} & - \frac{1}{2} \\ 0 & \frac{\sqrt{3}}{2} & - \frac{\sqrt{3}}{2}\end{matrix} ] [ \begin{matrix}{v}_{a} \\ {v}_{b} \\ {v}_{c}\end{matrix} ] \qquad [ Mathematical Formula 2 ]$$

$$[ \begin{matrix}{v}_{α} \\ {v}_{β}\end{matrix} ] = \sqrt{\frac{2}{3}} [ \begin{matrix}1 & - \frac{1}{2} & - \frac{1}{2} \\ 0 & \frac{\sqrt{3}}{2} & - \frac{\sqrt{3}}{2}\end{matrix} ] [ \begin{matrix}{v}_{a} \\ {v}_{b} \\ {v}_{c}\end{matrix} ]$$

The transformation expressed by the upper formula is referred to as “relative transformation” or “amplitude invariant transformation”, and the transformation expressed by the lower formula is referred to as “absolute transformation” or “power invariant transformation”. The scalar quantity depends on the used formula. In the case of a PLL circuit, the angle is important, so that either formula may be used.

### <Method of Applying Clarke Transformation and Inverse Clarke Transformation>

FIG. 7 is a schematic diagram illustrating a rotor vector. FIG. 7 shows an external rotor vector R1 of an external sine wave V1 and an internal rotor vector R2 of an internal sine wave V2 at a certain moment. Referring to FIG. 7, in a case where the frequencies of the external rotor vector R1 of the external sine wave V1 and the internal rotor vector R2 of the internal sine wave V2 are different, the angular velocities ω1 and ω2 of the vectors are also different from each other. For synchronization of the phase of the internal sine wave V2 with the phase of the external sine wave V1, an operation is to be performed for matching of the internal rotor vector R2 of the internal sine wave V2 with the external rotor vector R1 of the external sine wave V1. As a method for the matching, a method is conceivable in which an appropriate manipulated variable rotor vector R3 is added to the internal rotor vector R2 to match the internal rotor vector R2 with the external rotor vector R1. The appropriate manipulated variable rotor vector R3 is obtained by vector synthesis. The external rotor vector R1 and the internal rotor vector R2 rotate at angular velocities ω1 and ω2, respectively, and therefore the manipulated variable rotor vector R3 also rotates at an angular velocity ω3 corresponding to the angular velocities ω1 and ω2.

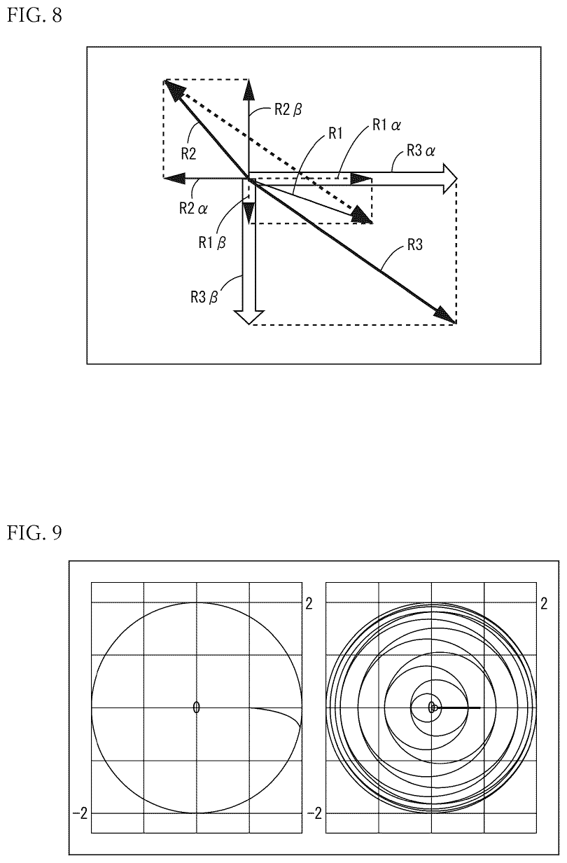

FIG. 8 is a vector diagram illustrating a vector operation for determination of the manipulated variable rotor vector R3. Referring to FIG. 8, α and β of each of the rotors of the external rotor vector R1 and the internal rotor vector R2 are obtained by Clarke transformation. α and β of the external rotor vector R1 are denoted by α1 and β1, respectively, and α and β of the internal rotor vector R2 are denoted by α2 and β2, respectively, thus determining an error of α, α1−α2=αerr, and an error of β, β1−β2=βerr. Then, appropriate compensation is applied to each of the error of α, αerr, and the error of β, βerr, and thus the manipulated variable rotor vector R3 is determined. The manipulated variable rotor vector R3 is added to the internal rotor vector R2 to perform closed-loop feedback control, and thus the internal rotor vector R2 matches with the external rotor vector R1.

FIG. 9 is a diagram illustrating a vector locus of the manipulated variable rotor vector R3 in the closed-loop feedback control. In FIG. 9, the diagram on the left side shows the vector locus of the manipulated variable rotor vector R3 in a case where the external rotor vector R1 and the internal rotor vector R2 have the same frequency and different phases. In this case, the two phases are different by 180°, and the maximum amplitude of the manipulated variable rotor vector R3 is twice the maximum amplitude of the external rotor vector R1 and the internal rotor vector R2. The diagram on the right side shows the vector locus of the manipulated variable rotor vector R3 in a case where the external rotor vector R1 and the internal rotor vector R2 have different frequencies and different phases. In this case, the two phases are different by 180°, and the maximum amplitude of the manipulated variable rotor vector R3 is twice the maximum amplitude of the external rotor vector R1 and the internal rotor vector R2. In this vector locus, a beat occurs due to the frequency component of the difference between the frequency of the external rotor vector R1 and the frequency of the internal rotor vector R2.

However, the addition in this method is not performed on a vector, but is performed on a time axis, and therefore this method needs transformation of the manipulated variable rotor vector R3 into a waveform. This transformation is inverse Clarke transformation. The inverse Clarke transformation is expressed by the following determinants. These determinants are obtained by only inverting the above-described determinants of Clarke transformation. The transformation expressed by the upper formula is referred to as “relative transformation” or “amplitude invariant transformation”. The transformation expressed by the lower formula is referred to as “absolute transformation” or “power invariant transformation”.

$$[ \begin{matrix}{v}_{a} \\ {v}_{b} \\ {v}_{c}\end{matrix} ] = [ \begin{matrix}1 & 0 \\ - \frac{1}{2} & \frac{\sqrt{3}}{2} \\ - \frac{1}{2} & - \frac{\sqrt{3}}{2}\end{matrix} ] [ \begin{matrix}{v}_{α} \\ {v}_{β}\end{matrix} ] \qquad [ Mathematical Formula 3 ]$$

$$[ \begin{matrix}{v}_{a} \\ {v}_{b} \\ {v}_{c}\end{matrix} ] = v [ \begin{matrix}1 & 0 \\ - \frac{1}{2} & \frac{\sqrt{3}}{2} \\ - \frac{1}{2} & - \frac{\sqrt{3}}{2}\end{matrix} ] [ \begin{matrix}{v}_{α} \\ {v}_{β}\end{matrix} ]$$

FIG. 2 shows a functional block diagram for execution of the closed-loop feedback control of a PLL circuit using Clarke transformation and inverse Clarke transformation described in this principle. In the functional block diagram of FIG. 2, the external three-phase voltage signal Ve corresponds to the external sine wave V1, the internal three-phase voltage signal Vi corresponds to the internal sine wave V2 at the start of control, and the sine wave reference three-phase voltage signal Vrs corresponds to the internal sine wave V2 after the start of control. The sine wave α voltage error signal Eαs and the sine wave β voltage error signal Eβs of the sine wave two-phase voltage error signal Eαβs correspond to the error of α, αerr, and the error of β, βerr, respectively, the sine wave two-phase voltage manipulated variable Oαβs corresponds to the manipulated variable rotor vector R3, and the sine wave three-phase voltage manipulated variable Oabcs corresponds to the manipulated variable rotor vector R3 transformed into a waveform. The external rotor vector, the reference rotor vector, and the manipulated variable rotor vector described in First Embodiment correspond to the external rotor vector R1, the internal rotor vector R2, and the manipulated variable rotor vector R3, respectively.

### [Operation]

Next, the operation of the reference three-phase voltage signal generation device 100A configured as described above will be described with reference to FIGS. 2, 7, and 8. Referring to FIGS. 2, 7, and 8, first, the reference three-phase voltage signal generation unit 2 adds the sine wave three-phase voltage manipulated variable Oabcs to the internal three-phase voltage signal Vi from the internal three-phase voltage signal generator 1, and outputs the sine wave reference three-phase voltage signal Vrs obtained by the addition to the outside.

Next, the first Clarke transformation unit 3 transforms the sine wave reference three-phase voltage signal Vrs from the reference three-phase voltage signal generation unit 2 into the sine wave reference two-phase voltage signal Vrαβs of the αβ coordinate system by Clarke transformation. Meanwhile, the second Clarke transformation unit 5 transforms the external three-phase voltage signal Ve from the external voltage signal sensor unit 4 into the sine wave external two-phase voltage signal Veαβs of the αβ coordinate system by Clarke transformation. The sine wave reference two-phase voltage signal Vrαβs and the sine wave external two-phase voltage signal Veαβs specify the external rotor vector R1 and the internal rotor vector R2, respectively. The external rotor vector R1 rotates at an angular velocity co corresponding to the frequency of the external three-phase voltage signal Ve before Clarke transformation. The internal rotor vector R2 rotates at an angular velocity ω2 corresponding to the frequency of the internal three-phase voltage signal Vi or the sine wave reference three-phase voltage signal Vrs before Clarke transformation.

Next, the error generation unit 6 generates an error of the sine wave reference two-phase voltage signal Vrαβs with respect to the sine wave external two-phase voltage signal Veαβs to generate the sine wave two-phase voltage error signal Eαβs. Next, the compensation unit 7 applies compensation to the sine wave two-phase voltage error signal Eαβs to generate the sine wave two-phase voltage manipulated variable Oαβs. This processing corresponds to processing in which the internal rotor vector R2 is subtracted from the external rotor vector R1 by a vector operation to obtain the manipulated variable rotor vector R3.

Next, the inverse Clarke transformation unit 8 transforms the sine wave two-phase voltage manipulated variable Oαβs into the sine wave three-phase voltage manipulated variable Oabcs of the abc coordinate system by inverse Clarke transformation.

Next, as described above, the reference three-phase voltage signal generation unit 2 adds the sine wave three-phase voltage manipulated variable Oabcs to the internal three-phase voltage signal Vi to generate the sine wave reference three-phase voltage signal Vrs. This processing corresponds to processing of adding the manipulated variable rotor vector R3 to the internal rotor vector R2 on the time axis.

Thereafter, the above-described closed-loop processing is repeated, and thus feedback control of the sine wave reference three-phase voltage signal Vrs is performed.

### [Simulation]

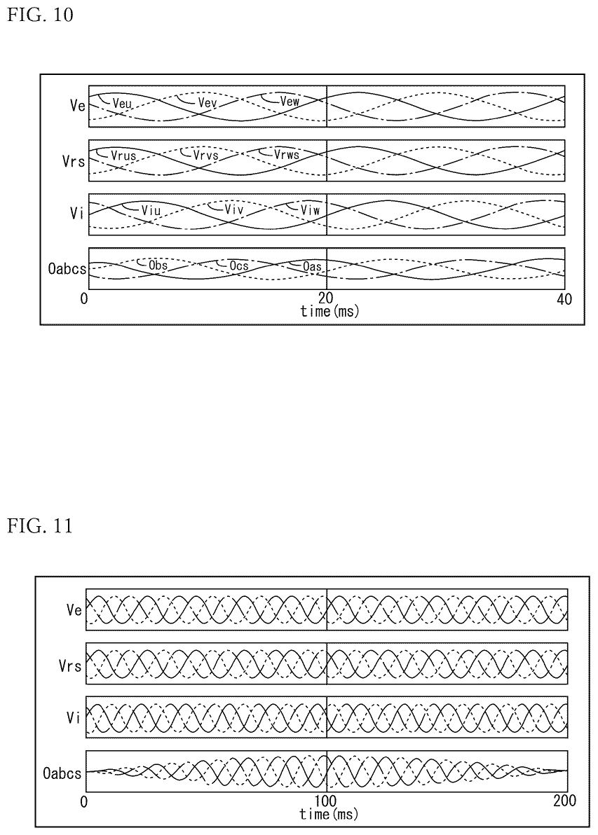

In order to confirm the operation of the reference three-phase voltage signal generation device 100A, simulation was performed using the circuit configuration of FIG. 2. FIG. 10 is a waveform diagram illustrating waveforms of signals of units of the reference three-phase voltage signal generation device 100A in a simulation of the reference three-phase voltage signal generation device 100A in a case where the external three-phase voltage signal Ve and the internal three-phase voltage signal Vi are different only in phase. FIG. 11 is a waveform diagram illustrating waveforms of signals of units of the reference three-phase voltage signal generation device 100A in a simulation of the reference three-phase voltage signal generation device 100A in a case where the external three-phase voltage signal Ve and the internal three-phase voltage signal Vi are different in frequency.

In FIGS. 10 and 11, the first-stage graph indicates the waveform of the external three-phase voltage signal Ve, the second-stage graph indicates the waveform of the sine wave reference three-phase voltage signal Vrs, the third-stage graph indicates the waveform of the internal three-phase voltage signal Vi, and the fourth-stage graph indicates the waveform of the sine wave three-phase voltage manipulated variable Oabcs. In the graph of each stage, the vertical axis represents amplitude, and the horizontal axis represents time (ms). In each graph, the solid line indicates the waveform of the U-phase signal, the broken line indicates the waveform of the V-phase signal, and the alternate long and short dash line indicates the waveform of the W-phase signal. Note that in the fourth-stage graph in FIG. 11, the scale on the vertical axis of the graph of the sine wave three-phase voltage manipulated variable Oabcs is twice the scale on the vertical axis of the other graphs.

Referring to FIG. 10, this simulation was performed under the condition that the external three-phase voltage signal Ve and the internal three-phase voltage signal Vi had the same frequency, and the phase of the internal three-phase voltage signal Vi was delayed by 45° from the phase of the external three-phase voltage signal Ve at the start. In this simulation result, the sum of the internal three-phase voltage signal Vi and the sine wave three-phase voltage manipulated variable Oabcs is the sine wave reference three-phase voltage signal Vrs, and the external three-phase voltage signal Ve and the sine wave reference three-phase voltage signal Vrs are equal.

Referring to FIG. 11, this simulation was performed under the condition that the external three-phase voltage signal Ve had a frequency of 50 Hz and the internal three-phase voltage signal Vi had a frequency of 55 Hz. In this simulation result, the external three-phase voltage signal Ve and the sine wave reference three-phase voltage signal Vrs are equal. Then, a beat component appears in the sine wave three-phase voltage manipulated variable Oabcs. The sine wave three-phase voltage manipulated variable Oabcs including the beat component has a waveform in which a sine wave signal having a frequency of 52.5 Hz fluctuates in a sine wave having a frequency of 5 Hz, and has an amplitude twice the amplitude of the external three-phase voltage signal Ve and the internal three-phase voltage signal Vi.

As described above, through these simulations, it has been confirmed that the reference three-phase voltage signal generation device 100A can synchronize the internal three-phase voltage signal Vi with the external three-phase voltage signal Ve and output the resulting signal as the sine wave reference three-phase voltage signal Vrs.

### [Effect]

According to Second Embodiment, the reference three-phase voltage signal generation device 100A can output the sine wave reference three-phase voltage signal Vrs. In the reference three-phase voltage signal generation device 100A, the speed of the sine wave reference three-phase voltage signal generation processing (synchronization processing) is determined by the speed of sampling the external three-phase voltage signal Ve. This sampling can be performed, for example, at 6 kHz, and in a case where the external three-phase voltage signal Ve has a frequency of 50 Hz, the control chance (chance of acquiring the external three-phase voltage signal Ve) occurs 120 times in one cycle of the external three-phase voltage signal Ve. Meanwhile, in zero-crossing detection, in a case where the external three-phase voltage has a frequency of 50 Hz, the control chance (chance of detecting a zero-crossing) occurs 1 time or 2 times in one cycle of the external three-phase voltage signal. Therefore, according to Second Embodiment, the speed of the sine wave reference three-phase voltage signal generation processing is remarkably faster than the processing speed in the conventional zero-crossing detection, and as a result, an apparatus using the sine wave reference three-phase voltage signal Vrs can respond at a high speed to a steep fluctuation of the voltage of the external three-phase power wiring 10.

### Third Embodiment

A reference three-phase voltage signal generation device 100B according to Third Embodiment is the reference three-phase voltage signal generation device 100 of First Embodiment in which the second Clarke transformation unit 5 applies Clarke transformation to the external three-phase voltage signal Ve and performs multiplication by a matrix for rotation by advance 90°. Therefore, the reference three-phase voltage signal generation device 100B generates a cosine wave reference three-phase voltage signal Vrc.

Comparing the reference three-phase voltage signal generation device 100B according to Third Embodiment with the reference three-phase voltage signal generation device 100A according to Second Embodiment, they are different in that in the reference three-phase voltage signal generation device 100A, the second Clarke transformation unit 5 only applies Clarke transformation to the external three-phase voltage signal Ve, whereas in the reference three-phase voltage signal generation device 100B, the second Clarke transformation unit 5 applies Clarke transformation to the external three-phase voltage signal Ve and performs multiplication by a matrix for rotation by advance 90°. The reference three-phase voltage signal generation devices 100A and 100B are similar in other points. Therefore, the difference will be mainly described below. For points not described below, the contents of Second Embodiment should be understood by reading Second Embodiment, regarding a signal with “sine wave” at the beginning of the name, with replacing “sine wave” in the name with “cosine wave” and replacing “s” at the end of the suffix in the reference sign with “c”.

### [Configuration and Operation]

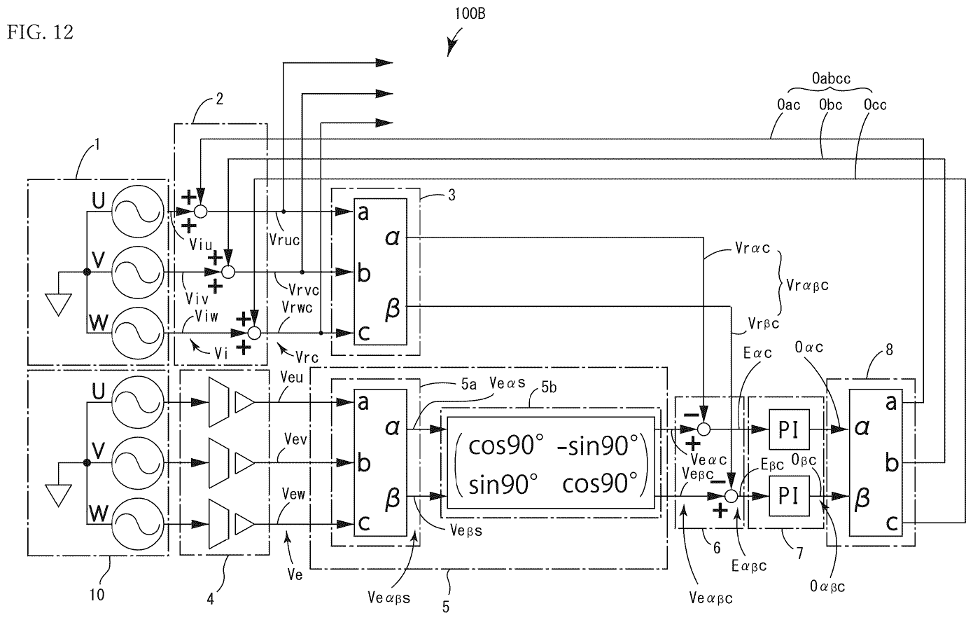

FIG. 12 shows a functional block diagram illustrating an example of a configuration of a reference three-phase voltage signal generation device according to Third Embodiment of the present disclosure.

Referring to FIG. 12, the reference three-phase voltage signal generation device 100B of Third Embodiment includes an internal three-phase voltage signal generator 1, a reference three-phase voltage signal generation unit 2, a first Clarke transformation unit 3, an external voltage signal sensor unit 4, a second Clarke transformation unit 5, an error generation unit 6, a compensation unit 7, and an inverse Clarke transformation unit 8.

The internal three-phase voltage signal generator 1 generates an internal three-phase voltage signal Vi. The reference three-phase voltage signal generation unit 2 adds a cosine wave three-phase voltage manipulated variable Oabcc to the internal three-phase voltage signal Vi from the internal three-phase voltage signal generator 1, and outputs a cosine wave reference three-phase voltage signal Vrc obtained by the addition to the outside. The first Clarke transformation unit 3 transforms the cosine wave reference three-phase voltage signal Vrc from the reference three-phase voltage signal generation unit 2 into a cosine wave reference two-phase voltage signal Vrαβc of an αβ coordinate system by Clarke transformation. Meanwhile, the external voltage signal sensor unit 4 acquires an external three-phase voltage signal Ve from an external three-phase power wiring 10.

The second Clarke transformation unit 5 applies Clarke transformation to the external three-phase voltage signal Ve from the external voltage signal sensor unit 4 and performs multiplication by a matrix for rotation by advance 90° to generate a cosine wave external two-phase voltage signal Veαβc of the αβ coordinate system.

A cosine wave has a 90° leading phase with respect to a sine wave. Therefore, multiplication of αβ of a sine wave by a matrix for rotation by advance 90° can transform αβ of the sine wave into αβ of a cosine wave. The operation of multiplying αβ of a sine wave by a matrix for rotation by advance 90° can be performed according to the following formula. As shown in the following formula, α of a cosine wave is −β of a sine wave, and β of a cosine wave is α of a sine wave.

$$[ Mathematical Formula 4 ]$$

$$( \begin{matrix}α \\ β\end{matrix} ) ( \begin{matrix}cos 90 ° & - sin 90 ° \\ sin 90 ° & cos 90 °\end{matrix} ) = ( \begin{matrix}α \\ β\end{matrix} ) ( \begin{matrix}0 & - 1 \\ 1 & 0\end{matrix} ) = ( \begin{matrix}- β \\ α\end{matrix} )$$

Specifically, the second Clarke transformation unit 5 includes a Clarke transformation unit 5a and a rotation matrix multiplication unit 5b. The second Clarke transformation unit 5a transforms the external three-phase voltage signal Ve from the external voltage signal sensor unit 4 into a sine wave external two-phase voltage signal Veαβs including a sine wave external α voltage signal Veαs and a sine wave external β voltage signal Veβs by Clarke transformation. The rotation matrix multiplication unit 5b multiplies the sine wave external two-phase voltage signal Veαβs by a matrix for rotation by advance 90° to generate a cosine wave external two-phase voltage signal Veαβc including a cosine wave external α voltage signal Veαc and a cosine wave external β voltage signal Veβc.

The error generation unit 6 generates an error of the cosine wave reference two-phase voltage signal Vrαβc from the first Clarke transformation unit 3 with respect to the cosine wave external two-phase voltage signal Veαβc from the second Clarke transformation unit 5 to generate a cosine wave two-phase voltage error signal Eαβc. The compensation unit 7 applies compensation to the cosine wave two-phase voltage error signal Eαβc from the error generation unit 6 to generate a cosine wave two-phase voltage manipulated variable Oαβc. The inverse Clarke transformation unit 8 transforms the cosine wave two-phase voltage manipulated variable Oαβc from the compensation unit 7 into the cosine wave three-phase voltage manipulated variable Oabcc of an abc coordinate system by inverse Clarke transformation, and inputs the cosine wave three-phase voltage manipulated variable Oabcc to the reference three-phase voltage signal generation unit 2.

As described above, the reference three-phase voltage signal generation unit 2 adds the cosine wave three-phase voltage manipulated variable Oabcc to the internal three-phase voltage signal Vi to generate the cosine wave reference three-phase voltage signal Vrc. Thereafter, the above-described closed-loop processing is repeated, and thus feedback control of the cosine wave reference three-phase voltage signal Vrc is performed.

Also in Third Embodiment, through the simulation, it has been confirmed that the reference three-phase voltage signal generation device 100B can generate the cosine wave reference three-phase voltage signal Vrc such that the internal three-phase voltage signal Vi has a 90° leading phase with respect to the external three-phase voltage signal Ve, and output the cosine wave reference three-phase voltage signal Vrc. The simulation results are similar to the conditions, and therefore the description thereof will be omitted.

### [Effect]

According to Third Embodiment, the reference three-phase voltage signal generation device 100B can output the cosine wave reference three-phase voltage signal Vrc. In the reference three-phase voltage signal generation device 100B, the speed of the cosine wave reference three-phase voltage signal generation processing (processing of advancing a phase by 90°) is determined by the speed of sampling the external three-phase voltage signal Ve. This sampling can be performed, for example, at 6 kHz, and in a case where the external three-phase voltage signal Ve has a frequency of 50 Hz, the control chance occurs 120 times in one cycle of the external three-phase voltage signal Ve. Meanwhile, in zero-crossing detection, in a case where the external three-phase voltage has a frequency of 50 Hz, the control chance occurs 1 time or 2 times in one cycle of the external three-phase voltage signal. Therefore, according to Third Embodiment, the speed of the cosine wave reference three-phase voltage signal generation processing is remarkably faster than the processing speed in the conventional zero-crossing detection, and as a result, an apparatus using the cosine wave reference three-phase voltage signal Vrc can respond at a high speed to a steep fluctuation of the voltage of the external three-phase power wiring 10.

### Fourth Embodiment

Fourth Embodiment of the present disclosure illustrates a reference three-phase voltage signal-using apparatus 1000A that uses only the sine wave reference three-phase voltage signal Vrs, which is an effective component, as the reference three-phase voltage signal Vr.

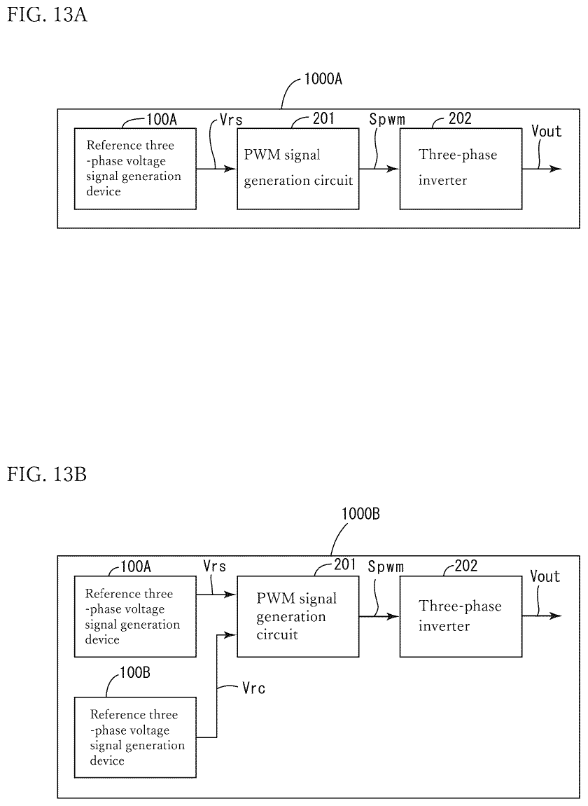

FIG. 13A is a functional block diagram illustrating an example of a configuration of the reference three-phase voltage signal-using apparatus 1000A according to Fourth Embodiment of the present disclosure.

Referring to FIG. 13A, the reference three-phase voltage signal-using apparatus 1000A includes the reference three-phase voltage signal generation device 100A of Second Embodiment, a PWM signal generation circuit 201, and a three-phase inverter 202.

Examples of the reference three-phase voltage signal-using apparatus 1000A include system interconnection power sources such as a UPS, a constant voltage constant frequency power source (CVCF), and a high power factor converter (PFC). In such a system interconnection power source, the power source targeted for synchronization is a commercial power source (power supply system). Of course, the reference three-phase voltage signal-using apparatus 1000A may be a power source device that targets the voltage of a general three-phase power source (external three-phase power wiring), other than the commercial power sources, for synchronization.

The reference three-phase voltage signal generation device 100A outputs the sine wave reference three-phase voltage signal Vrs synchronized with the voltage of a predetermined three-phase power source. The PWM signal generation circuit 201 generates and outputs a PWM signal corresponding to the sine wave reference three-phase voltage signal Vrs. The three-phase inverter 202 outputs a three-phase voltage Vout synchronized with the voltage of the predetermined three-phase power source according to the PWM signal.

According to Fourth Embodiment, such a reference three-phase voltage signal-using apparatus can be provided that uses the sine wave reference three-phase voltage signal Vrs and can respond at a high speed to a steep fluctuation of the three-phase voltage of a predetermined three-phase power source targeted for synchronization.

### Fifth Embodiment

Fifth Embodiment of the present disclosure illustrates a reference three-phase voltage signal-using apparatus 1000B that uses the sine wave reference three-phase voltage signal Vrs, which is an effective component, and the cosine wave reference three-phase voltage signal Vrc, which is an ineffective component, as the reference three-phase voltage signal Vr.

FIG. 13B is a functional block diagram illustrating an example of a configuration of the reference three-phase voltage signal-using apparatus 1000B according to Fifth Embodiment of the present disclosure.

Referring to FIG. 13B, the reference three-phase voltage signal-using apparatus 1000B includes the reference three-phase voltage signal generation device 100A of Second Embodiment, the reference three-phase voltage signal generation device 100B of Third Embodiment, a PWM signal generation circuit 201, and a three-phase inverter 202.

Examples of the reference three-phase voltage signal-using apparatus 1000B include a power conditioning system (PCS). In this system interconnection power source, the power source is a commercial power source (power supply system). Of course, the reference three-phase voltage signal-using apparatus 1000B may be a power source device that targets the voltage of a general three-phase power source (external three-phase power wiring), other than the commercial power sources, for synchronization or the like.

The reference three-phase voltage signal generation device 100A outputs the sine wave reference three-phase voltage signal Vrs synchronized with the voltage of a predetermined three-phase power source. The reference three-phase voltage signal generation device 100B outputs the cosine wave reference three-phase voltage signal Vrc having a 90° leading phase with respect to the voltage of the predetermined three-phase power source. The PWM signal generation circuit 201 generates and outputs PWM signals corresponding to the sine wave reference three-phase voltage signal Vrs and the cosine wave reference three-phase voltage signal Vrc. The three-phase inverter 202 outputs a three-phase voltage Vout synchronized with the voltage of the predetermined three-phase power source and having an effective power and a reactive power under control according to the PWM signals.

According to Fifth Embodiment, such a reference three-phase voltage signal-using apparatus can be provided that uses the sine wave reference three-phase voltage signal Vrs and the cosine wave reference three-phase voltage signal Vrc and can respond at a high speed to a steep fluctuation of the three-phase voltage of a predetermined three-phase power source targeted for synchronization or the like.

From the above description, many modifications and other embodiments are apparent to those skilled in the art. Therefore, the above description is to be interpreted only as an example.

The reference three-phase voltage signal generation device and the reference three-phase voltage signal-using apparatus of the present disclosure are useful as a reference three-phase voltage signal generation device and a reference three-phase voltage signal-using apparatus that are capable of responding at a high speed to a steep fluctuation of the three-phase voltage of an external three-phase power wiring targeted for synchronization or the like.

What is claimed is:

1. A reference three-phase voltage signal generation device comprising:
an internal three-phase voltage signal generator that generates an internal three-phase voltage signal;
a reference three-phase voltage signal generation unit that adds a three-phase voltage manipulated variable to the internal three-phase voltage signal from the internal three-phase voltage signal generator to obtain a reference three-phase voltage signal, and outputs the reference three-phase voltage signal outside;
a first Clarke transformation unit that transforms the reference three-phase voltage signal from the reference three-phase voltage signal generation unit into a reference two-phase voltage signal of an αβ coordinate system by Clarke transformation;
an external voltage signal sensor unit that acquires an external three-phase voltage signal from an external three-phase power wiring;
a second Clarke transformation unit that applies Clarke transformation to the external three-phase voltage signal from the external voltage signal sensor unit, or applies Clarke transformation to the external three-phase voltage signal and performs multiplication by a matrix for rotation by advance 90° to generate an external two-phase voltage signal of the αβ coordinate system;
an error generation unit that generates an error of the reference two-phase voltage signal from the first Clarke transformation unit with respect to the external two-phase voltage signal from the second Clarke transformation unit to generate a two-phase voltage error signal;
a compensation unit that applies compensation to the two-phase voltage error signal from the error generation unit to generate a two-phase voltage manipulated variable; and
an inverse Clarke transformation unit that transforms the two-phase voltage manipulated variable from the compensation unit into the three-phase voltage manipulated variable of an abc coordinate system by inverse Clarke transformation, and inputs the three-phase voltage manipulated variable to the reference three-phase voltage signal generation unit.

2. The reference three-phase voltage signal generation device according to claim 1, wherein
the internal three-phase voltage signal includes an internal U-phase voltage signal, an internal V-phase voltage signal, and an internal W-phase voltage signal that are an internal a voltage signal, an internal b voltage signal, and an internal c voltage signal in the abc coordinate system, respectively,
the external three-phase voltage signal includes an external U-phase voltage signal, an external V-phase voltage signal, and an external W-phase voltage signal that are an external a voltage signal, an external b voltage signal, and an external c voltage signal in the abc coordinate system, respectively,
the reference three-phase voltage signal generation unit adds an a voltage manipulated variable, a b voltage manipulated variable, and a c voltage manipulated variable of the three-phase voltage manipulated variable to the internal a voltage signal, the internal b voltage signal, and the internal c voltage signal of the internal three-phase voltage signal from the internal three-phase voltage signal generator, respectively, to obtain the reference three-phase voltage signal including a reference U-phase voltage signal as a reference a voltage signal, a reference V-phase voltage signal as a reference b voltage signal, and a reference W-phase voltage signal as a reference c voltage signal, and outputs the reference three-phase voltage signal outside,
the first Clarke transformation unit transforms the reference three-phase voltage signal including the reference a voltage signal, the reference b voltage signal, and the reference c voltage signal from the reference three-phase voltage signal generation unit into the reference two-phase voltage signal including a reference α voltage signal and a reference β voltage signal of the αβ coordinate system by Clarke transformation,
the second Clarke transformation unit applies Clarke transformation to the external three-phase voltage signal including the external a voltage signal, the external b voltage signal, and the external c voltage signal from the external voltage signal sensor unit, or applies Clarke transformation to the external three-phase voltage signal and performs multiplication by a matrix for rotation by advance 90° to generate the external two-phase voltage signal including an external α voltage signal and an external β voltage signal of the αβ coordinate system,
the error generation unit generates the two-phase voltage error signal including an α voltage error signal and a β voltage error signal that are an error of the reference α voltage signal and an error of the reference β voltage signal of the reference two-phase voltage signal from the first Clarke transformation unit with respect to the external α voltage signal and the external β voltage signal of the external two-phase voltage signal from the second Clarke transformation unit, respectively,
the compensation unit applies compensation to each of the α voltage error signal and the β voltage error signal of the two-phase voltage error signal from the error generation unit to generate the two-phase voltage manipulated variable including an α voltage manipulated variable and a β voltage manipulated variable, and
the inverse Clarke transformation unit transforms the two-phase voltage manipulated variable including the α voltage manipulated variable and the β voltage manipulated variable from the compensation unit into the three-phase voltage manipulated variable including the a voltage manipulated variable, the b voltage manipulated variable, and the c voltage manipulated variable of the abc coordinate system by inverse Clarke transformation, and inputs the three-phase voltage manipulated variable to the reference three-phase voltage signal generation unit.

3. The reference three-phase voltage signal generation device according to claim 1, wherein
the reference three-phase voltage signal generation unit adds a sine wave three-phase voltage manipulated variable to the internal three-phase voltage signal from the internal three-phase voltage signal generator to obtain a sine wave reference three-phase voltage signal, and outputs the sine wave reference three-phase voltage signal outside,
the first Clarke transformation unit transforms the sine wave reference three-phase voltage signal from the reference three-phase voltage signal generation unit into a sine wave reference two-phase voltage signal of the αβ coordinate system by Clarke transformation,
the second Clarke transformation unit applies Clarke transformation to the external three-phase voltage signal from the external voltage signal sensor unit to generate a sine wave external two-phase voltage signal of the αβ coordinate system,
the error generation unit generates a sine wave two-phase voltage error signal as an error of the sine wave reference two-phase voltage signal from the first Clarke transformation unit with respect to the sine wave external two-phase voltage signal from the second Clarke transformation unit,
the compensation unit applies compensation to the sine wave two-phase voltage error signal from the error generation unit to generate a sine wave two-phase voltage manipulated variable, and
the inverse Clarke transformation unit transforms the sine wave two-phase voltage manipulated variable from the compensation unit into the sine wave three-phase voltage manipulated variable of the abc coordinate system by inverse Clarke transformation, and inputs the sine wave three-phase voltage manipulated variable to the reference three-phase voltage signal generation unit.

4. The reference three-phase voltage signal generation device according to claim 1, wherein
the reference three-phase voltage signal generation unit adds a cosine wave three-phase voltage manipulated variable to the internal three-phase voltage signal from the internal three-phase voltage signal generator to obtain a cosine wave reference three-phase voltage signal, and outputs the cosine wave reference three-phase voltage signal outside,
the first Clarke transformation unit transforms the cosine wave reference three-phase voltage signal from the reference three-phase voltage signal generation unit into a cosine wave reference two-phase voltage signal of the αβ coordinate system by Clarke transformation,
the second Clarke transformation unit includes a Clarke transformation unit and a rotation matrix multiplication unit, the Clarke transformation unit that applies Clarke transformation to the external three-phase voltage signal from the external voltage signal sensor unit to generate a sine wave external two-phase voltage signal of the αβ coordinate system, and the rotation matrix multiplication unit that multiplies the sine wave external two-phase voltage signal by a matrix for rotation by advance 90° to generate a cosine wave external two-phase voltage signal,
the error generation unit generates a cosine wave two-phase voltage error signal as an error of the cosine wave reference two-phase voltage signal from the first Clarke transformation unit with respect to the cosine wave external two-phase voltage signal from the rotation matrix multiplication unit of the second Clarke transformation unit,
the compensation unit applies compensation to the cosine wave two-phase voltage error signal from the error generation unit to generate a cosine wave two-phase voltage manipulated variable, and
the inverse Clarke transformation unit transforms the cosine wave two-phase voltage manipulated variable from the compensation unit into the cosine wave three-phase voltage manipulated variable of the abc coordinate system by inverse Clarke transformation, and inputs the cosine wave three-phase voltage manipulated variable to the reference three-phase voltage signal generation unit.

5. The reference three-phase voltage signal generation device according to claim 1, wherein the compensation unit performs proportional integral (PI) compensation on the two-phase voltage error signal.

6. A reference three-phase voltage signal-using apparatus comprising:
the reference three-phase voltage signal generation device according to claim 1; and
a three-phase inverter that outputs a three-phase voltage synchronized with a three-phase voltage of the external three-phase power wiring by pulse width modulation (PWM) control according to the reference three-phase voltage signal.

7. The reference three-phase voltage signal-using apparatus according to claim 6, wherein
the reference three-phase voltage signal generation device outputs the reference three-phase voltage signal from the reference three-phase voltage signal generation unit, the reference three-phase voltage signal synchronized with a three-phase voltage of a power supply system as the external three-phase power wiring, and
the three-phase inverter outputs a three-phase voltage synchronized with the three-phase voltage of the power supply system by PWM control according to the reference three-phase voltage signal.
